(19) United States
(12) Patent Application Publication
(10) Pub. No.: US 2013/0000695 A1
(43) Pub. Date: Jan. 3, 2013

(54) LIGHT HARVESTING IN PHOTOVOLTAIC SYSTEMS

(75) Inventor: Sandeep Giri, Mountain View, CA (US)

(73) Assignee: QUALCOMM MEMS TECHNOLOGIES, INC., San Diego, CA (US)

(21) Appl. No.: 13/196,757

(22) Filed: Aug. 2, 2011

Related U.S. Application Data
(60) Provisional application No. 61/503,097, filed on Jun. 30, 2011.

(51) Int. Cl. H01L 31/052; B23P 11/00

(52) U.S. Cl. 136/246; 29/428

(57) ABSTRACT

This disclosure provides methods and apparatus for increasing the efficiency of a photovoltaic module. In one aspect, an apparatus includes an array of photovoltaic cells. One or more reflective surfaces can be provided along the edges of the array, between the edges of the array and the frame. The reflective surfaces can extend in a direction from the back of the array toward the front of the array so as to reflect light exiting the first and second edges of the array back into the array through the first and second edges. The reflective surface can be convex and/or can be disposed at one or more angles with respect to the array. The angles can be selected based on a selected geographical latitude and a corresponding selected orientation of the array relative to the sun.

### CROSS-REFERENCE TO RELATED APPLICATIONS

This disclosure claims priority to U.S. Provisional Patent Application No. 61/503,097, filed Jun. 30, 2011, entitled “Light Harvesting in Photovoltaic Systems,” and assigned to the assignee hereof. The disclosure of the prior application is considered part of, and is incorporated by reference in, this disclosure.

### TECHNICAL FIELD

This disclosure relates generally to the field of optoelectronic devices that convert optical energy into electrical energy, for example, photovoltaic devices.

### DESCRIPTION OF THE RELATED TECHNOLOGY

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the availability of fossil fuel. In addition, geopolitical issues can quickly affect the supply of such fuel. Global warming is also of greater concern in recent years. A number of factors are thought to contribute to global warming; however, widespread use of fossil fuels is presumed to be a main cause of global warming. Thus there is an urgent need to find a renewable and economically viable source of energy that is also environmentally safe. Solar energy is an environmentally friendly renewable source of energy that can be converted into other forms of energy such as heat and electricity.

Photovoltaic cells convert optical energy to electrical energy and thus can be used to convert solar energy into electrical power. Photovoltaic solar cells can be made very thin and modular. Photovoltaic cells can range in size from a about few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Photovoltaic cells can be used in a wide range of applications such as providing power to satellites and other spacecraft, providing electricity to residential and commercial properties, charging automobile batteries, etc.

While photovoltaic devices have the potential to reduce reliance upon fossil fuels, the widespread use of photovoltaic devices has been hindered by inefficiency concerns and concerns regarding the material costs required to produce such devices. Accordingly, improvements in efficiency and/or manufacturing costs could increase usage of photovoltaic devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus including an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array; a first reflector extending in a direction from the back side of the array toward the front side of the array, the first reflector having a first convex reflective surface disposed along at least a portion of the first edge; and a second reflector extending in a direction from the back side of the array toward the front side of the array, the second reflector having a second convex reflective surface disposed along at least a portion of the second edge, wherein the first and second reflectors are respectively positioned in a direction to reflect light that exits the first and second edges of the array back into the array through the first and second edges. In one implementation, the apparatus can include a frame disposed along at least the first and second edges of the array, wherein the first and second reflectors are respectively located between the frame and the first and second edges of the array. In another implementation, each photovoltaic cell can include a photovoltaic active layer, and at least one of the first and second reflective surfaces can be spaced apart laterally from the photovoltaic active layer of at least one of the photovoltaic cells. In another implementation, the apparatus can include an optical element disposed between the photovoltaic active layer and the at least one of the first and second reflective surfaces. In another implementation, the array can further include a third edge along the periphery of the array and a fourth edge along the periphery of the array, the third and fourth edges located on opposite sides of the array, the third and fourth edges extending in a direction normal to the first and second edges, and the apparatus can further include a third reflector extending in a direction from the back side of the array toward the front side of the array, the third reflector having a third reflective surface disposed along at least a portion of the third edge, at least a portion of the third reflective surface being disposed at a third angle with respect to the array plane; and a fourth reflector extending in a direction from the back side of the array toward the front side of the array, the fourth reflector having a fourth reflective surface disposed along at least a portion of the fourth edge, at least a portion of the fourth reflective surface being disposed at a fourth angle with respect to the array plane, wherein the third and fourth reflectors are respectively positioned in a direction to reflect light that exits the third and fourth edges of the array back into the array through the third and fourth edges, and wherein and the third and fourth angles are selected based on a selected geographical latitude and a corresponding selected orientation of the array relative to the sun. At least one of, or both of, the third and fourth angles can be acute angles with respect to the array plane.

In another aspect, a method includes providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array; providing a first reflector extending in a direction from the back side of the array toward the front side of the array, the first reflector having a first convex reflective surface disposed along at least a portion of the first edge; and providing a second reflector extending in a direction from the back side of the array toward the front side of the array, the second reflector having a second convex reflective surface disposed along at least a portion of the second edge, wherein the first and second reflectors are respectively positioned in a direction to reflect light that exits the first and second edges of the array back into the array through the first and second edges. In one implementation, the method can further include providing a frame disposed along at least the first and second edges of the array, wherein the first and second reflectors are respectively located between the frame and the first and second edges of the array.

In another aspect, a method of manufacturing a photovoltaic module includes providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array; selecting an orientation for the array based on a selected geographical latitude; providing a first reflector extending in a direction from the back side of the array toward the front side of the array, the first reflector having a first reflective surface disposed along at least a portion of the first edge, at least a portion of the first reflective surface of the first reflector being disposed at a first angle non-normal to the array plane, the first angle being selected based on a location of the first edge in the periphery of the array and the selected orientation of the array; and providing a second reflector extending in a direction from the back side of the array toward the front side of the array, the second reflector having a second reflective surface disposed along at least a portion of the second edge, at least a portion of the second reflective surface of the second reflector being disposed at a second angle non-normal to the array plane, the second angle being selected based on a location of the second edge in the periphery of the array and the selected orientation of the array, wherein the first and second reflectors are respectively positioned in a direction to reflect light that exits the first and second edges of the array back into the array through the first and second edges. In one implementation, the method can further include providing a frame disposed along at least the first and second edges of the array, wherein the first and second reflectors are respectively located between the frame and the first and second edges of the array. In another implementation, the first angle can be an acute angle with respect to the array plane and the second angle can be an obtuse angle with respect to the array plane. In another implementation, each photovoltaic cell can include a photovoltaic active layer, and at least one of the first and second reflective surfaces can be spaced apart laterally from the photovoltaic active layer of at least one of the photovoltaic cells. In another implementation, the method can further include providing an optical element disposed between the photovoltaic active layer and the at least one of the first and second reflective surfaces.

In another aspect, an apparatus includes an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array; a first reflector extending in a direction from the back side of the array toward the front side of the array, the first reflector having a first reflective surface disposed along at least a portion of the first edge, at least a portion of the first reflective surface of the first reflector being disposed at a first angle non-normal to the array plane; and a second reflector extending in a direction from the back side of the array toward the front side of the array, the second reflector having a second reflective surface disposed along at least a portion of the second edge, at least a portion of the second reflective surface of the second reflector being disposed at a second angle non-normal to the array plane, and wherein the first and second reflectors are respectively positioned in a direction to reflect light that exits the first and second edges of the array back into the array through the first and second edges. The first and second angles can be selected based on a selected geographical latitude and a corresponding selected orientation of the array relative to the sun. In one implementation, the first angle can be an acute angle with respect to the array plane and the second angle can be an obtuse angle with respect to the array plane. In another implementation, each photovoltaic cell can include a photovoltaic active layer, and at least one of the first and second reflective surfaces can be spaced apart laterally from the photovoltaic active layer of at least one of the photovoltaic cells. In another implementation, an optical element can be disposed between the photovoltaic active layer and the at least one of the first and second reflective surfaces.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1A is an example of a cross-section of one implementation of a photovoltaic cell including a p-n junction.

FIG. 1B is an example of a block diagram that schematically illustrates a cross-section of one example of a photovoltaic cell including a deposited thin film photovoltaic active material.

FIGS. 2A and 2B are examples of schematic plan and isometric sectional views depicting an example solar photovoltaic device with reflective electrodes on the front side.

FIG. 3 schematically depicts an example of two photovoltaic cells connected by a tab or ribbon.

FIG. 4 is an example of a schematic plan view of an array of photovoltaic cells in a photovoltaic module.

FIGS. 5A-5F show examples of cross-sectional views of various implementations of photovoltaic modules including boundary reflectors.

FIGS. 6A-6C show examples of cross-sectional views of additional implementations of photovoltaic modules including boundary reflectors.

FIGS. 7A, 7B, and 7C are examples of schematic plan and cross-sectional views of a photovoltaic module according to one implementation.

FIGS. 8A, 8B, and 8C are examples of schematic plan and cross-sectional views of a photovoltaic module according to another implementation.

FIGS. 9A, 9B, and 9C are examples of schematic plan and cross-sectional views of a photovoltaic module according to yet another implementation.

FIG. 10A is an example of a block diagram schematically illustrating one implementation of a method of manufacturing a photovoltaic module.

FIG. 10B is an example of a block diagram schematically illustrating another implementation of a method of manufacturing a photovoltaic module.

Like reference numbers and designations in the various drawings indicate like elements.

### DETAILED DESCRIPTION

Implementations of a photovoltaic (PV) apparatus disclosed herein include PV modules that include an array of photovoltaic devices (e.g., photovoltaic cells). The PV devices in the array can be positioned adjacent to each other in a planar arrangement. A PV module can include a frame surrounding the array of PV devices along the periphery of the array, and have one or more reflective surfaces disposed at edges of the array between the PV devices at the edge of the array and the frame. The reflective surfaces can extend in a direction from the back of the array towards a front light receiving surface of the array. For example, the reflective surfaces can extend in a direction generally normal to the planar arrangement of the PV devices in the array, or at an angle to the plane of the array. The shape of the reflective surfaces can be planar, curved, or include more than one planar facet and or curved surface. The reflective surfaces can be positioned adjacent to one or more edges of the array to reflect light that is emitted from an edge of the array back into the array. With such an arrangement, at least a portion of light propagating toward one or more edges of the array and out of the edges of the array, which might otherwise be absorbed or reflected in some undetermined direction by the frame or other material (e.g., glue) surrounding the array, is reflected back into the array of PV devices. The reflective surfaces can be arranged to redirect that light back toward the photovoltaic devices or portions thereof, increasing the amount of light available for absorption by the photovoltaic devices and increasing the overall efficiency of the module (e.g., the amount of electrical power produced by the PV module for a given amount of incident light). In some implementations, a PV module can include differently-shaped or differently-angled reflective surfaces on different edges of the array, for example, opposing edges of the array that are on opposite sides of the array. In some implementations, the shape of the reflective surfaces and/or the angle of the reflective surfaces with respect to the plane of the array can be selected to optimize the PV module for a selected geographical location (e.g., a particular latitude), a selected time (e.g., a selected time of day or a particular season), and/or a particular position of an edge of the array relative to the sun.

Particular implementations of the subject matter described in this disclosure can be implemented to realize one or more of the following potential advantages. Some implementations can be used to increase the efficiency of a photovoltaic module, for example by reducing the amount of light lost at the edges of the module to absorption by the frame or other surrounding material. The increase in short circuit current density and, thus, output power, that may be achieved by some implementations can be 3% or higher.

Although certain implementations and examples are discussed herein, it is understood that the inventive subject matter extends beyond the specifically disclosed implementations to other alternative implementations and/or uses of the invention and obvious modifications and equivalents thereof. It is intended that the scope of the inventions disclosed herein should not be limited by the particular disclosed implementations. Thus, for example, in any method or process disclosed herein, the acts or operations making up the method/process may be performed in any suitable sequence and are not necessarily limited to any particular disclosed sequence. Various aspects and features of the implementations have been described where appropriate. It is to be understood that not necessarily all such aspects or features may be achieved in accordance with any particular implementation. Thus, for example, it should be recognized that the various implementations may be carried out in a manner that achieves or optimizes one feature or group of features as taught herein without necessarily achieving other aspects or features as may be taught or suggested herein. The following detailed description is directed to certain specific implementations of the invention. However, the invention can be implemented in a multitude of different ways. The implementations described herein may be implemented in a wide range of devices that incorporate photovoltaic devices for conversion of optical energy into electrical current.

In this description, reference is made to the drawings wherein like parts are designated with like numerals throughout. As will be apparent from the following description, the implementations may be implemented in a variety of devices that include photovoltaic active material.

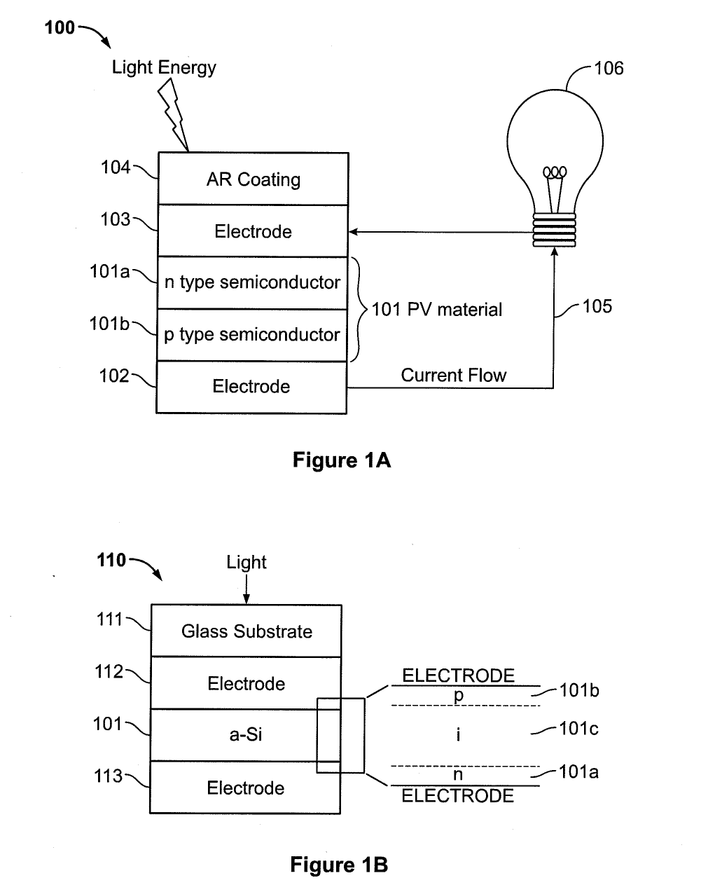

Turning now to the Figures, FIG. 1A is an example of a cross-section of one implementation of a photovoltaic cell including a p-n junction. A photovoltaic cell can convert light energy into electrical energy or current. A photovoltaic cell is an example of a renewable source of energy that has a small carbon footprint and has less impact on the environment. Using photovoltaic cells can reduce the cost of energy generation. Photovoltaic cells can have many different sizes and shapes, e.g., from smaller than a postage stamp to several inches across. Several photovoltaic cells can often be connected together to form photovoltaic cell modules up to several feet long and several feet wide. Modules, in turn, can be combined and connected to form photovoltaic arrays of different sizes and power output.

The size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A “photovoltaic device” as used herein can be a single photovoltaic cell (including its attendant electrical connections and peripherals), a photovoltaic module, a photovoltaic array, or solar panel. A photovoltaic device can also include functionally unrelated electrical components, e.g., components that are powered by the photovoltaic cell(s).

With reference to FIG. 1A, a photovoltaic cell 100 includes a photovoltaic active region 101 disposed between two electrodes 102, 103. In some implementations, the photovoltaic cell 100 includes a substrate on which a stack of layers is formed. The photovoltaic active layer 101 of a photovoltaic cell 100 may include a semiconductor material, for example, silicon. In some implementations, the active region may include a p-n junction formed by contacting an n-type semiconductor material 101a and a p-type semiconductor material 101b as shown in FIG. 1A. Such a p-n junction may have diode-like properties and may therefore be referred to as a photodiode structure as well.

The photovoltaic active material 101 is sandwiched between two electrodes that provide an electrical current path. The back electrode 102 can be formed of aluminum, silver, or molybdenum or some other conducting material. The front electrode 103 may be designed to cover a significant portion of the front surface of the p-n junction so as to lower contact resistance and increase collection efficiency. In implementations wherein the front electrode 103 is formed of an opaque material, the front electrode 103 may be configured to leave openings over the front of the photovoltaic active layer 101 to allow illumination to impinge on the photovoltaic active layer 101. In some implementations, the front and back electrodes 103, 102 can include a transparent conductor, for example, transparent conducting oxide (TCO), for example, aluminum-doped zinc oxide (ZnO:Al), fluorine-doped tin Oxide (SnO₂:F), or indium tin oxide (ITO). The TCO can provide electrical contact and conductivity and simultaneously be transparent to incident radiation, including light. In some implementations, the front electrode 103 disposed between the source of light energy and the photovoltaic active material 101 can include one or more optical elements that redirect a portion of incident light. The optical elements can include, for example, diffusers, holograms, roughened interfaces, and/or diffractive optical elements including microstructures formed on various surfaces or formed within volumes. For example, roughened surface interfaces can be used to scatter light beams that pass therethrough. The scattering of light can increase the light absorbing path of the scattered light beams through the photovoltaic active material 101 and thus increase the electrical power output of the cell 100. In some implementations, the photovoltaic cell 100 can also include an anti-reflective (AR) coating 104 disposed over the front electrode 103. The AR coating 104 can reduce the amount of light reflected from the front surface of the photovoltaic active material 101.

When the front surface of the photovoltaic active material 101 is illuminated, photons transfer energy to electrons in the active region. If the energy transferred by the photons is greater than the band-gap of the semiconducting material, the electrons may have sufficient energy to enter the conduction band. An internal electric field is created with the formation of the p-n junction or p-i-n junction. The internal electric field operates on the energized electrons to cause these electrons to move, thereby producing a current flow in an external circuit 105. The resulting current flow can be used to power various electrical devices, for example, a light bulb 106 as shown in FIG. 1A, or to generate electricity for distribution to other devices, or to a distribution grid.

The photovoltaic active material layer(s) 101 can be formed by any of a variety of light absorbing, photovoltaic materials, for example, microcrystalline silicon (μc-silicon), amorphous silicon (a-silicon), cadmium telluride (CdTe), copper indium diselenide (CIS), copper indium gallium diselenide (CIGS), light absorbing dyes and polymers, polymers dispersed with light absorbing nanoparticles, III-V semiconductors, for example, GaAs, etc. Other materials may also be used. The light absorbing material(s) where photons are absorbed and transfer energy to electrical carriers (holes and electrons) is referred to herein as the photovoltaic active layer 101 or material of the photovoltaic cell 100, and this term is meant to encompass multiple active sub-layers. The material for the photovoltaic active layer 101 can be chosen depending on the desired performance and the application of the photovoltaic cell. In implementations where there are multiple active sublayers, one or more of the sublayers can include the same or different materials.

In some arrangements, the photovoltaic cell 100 can be formed by using thin film technology. For example, in one implementation, where optical energy passes through a transparent substrate, the photovoltaic cell 100 may be formed by depositing a first or front electrode layer 103 of TCO on a substrate. The substrate layer and the transparent conductive oxide layer 103 can form a substrate stack that may be provided by a manufacturer to an entity that subsequently deposits a photovoltaic active layer 101 thereon. After the photovoltaic active layer 101 has been deposited, a second electrode layer 102 can be deposited on the layer of photovoltaic active material 101. The layers may be deposited using deposition techniques including physical vapor deposition techniques, chemical vapor deposition techniques, for example, plasma-enhanced chemical vapor deposition, and/or electro-chemical vapor deposition techniques, etc. Thin film photovoltaic cells may include amorphous, monocrystalline, or polycrystalline materials, for example, silicon, thin-film amorphous silicon, CIS, CdTe or CIGS. Thin film photovoltaic cells facilitate small device footprint and scalability of the manufacturing process.

FIG. 1B is an example of a block diagram that schematically illustrates a cross-section of one example of a photovoltaic cell including a deposited thin film photovoltaic active material. The photovoltaic cell 110 includes a glass substrate layer 111 through which light can pass. Disposed on the glass substrate 111 are a first electrode layer 112, a photovoltaic active layer 101 (shown as including amorphous silicon), and a second electrode layer 113. The first electrode layers 112 can include a transparent conducting material, for example, ITO. As illustrated, the first electrode layer 112 and the second electrode layer 113 sandwich the thin film photovoltaic active layer 101 therebetween. The illustrated photovoltaic active layer 101 includes an amorphous silicon layer. As is known in the art, amorphous silicon serving as a photovoltaic material may include one or more diode junctions. Furthermore, an amorphous silicon photovoltaic layer or layers may include a p-i-n junction wherein a layer of intrinsic silicon 101c is sandwiched between a p-doped layer 101b and an n-doped layer 101a. A p-i-n junction may have higher efficiency than a p-n junction. In some other implementations, the photovoltaic cell 110 can include multiple junctions.

Photovoltaic cells can include a network of conductors that are disposed on the front surface of the cells and electrically connected to the photocurrent-generating substrate material. The conductors can be electrodes formed over the photovoltaic material of a photovoltaic device (including thin film photovoltaic devices) or the conductors may be tabs (ribbons) connecting individual devices together in a module and/or array. Photons entering a photovoltaic active material generate carriers throughout the material (except in the shadowed areas under the overlying conductors). The negatively and positively charged carriers (electrons and holes respectively), once generated, can travel only a limited distance through the photovoltaic active material before the carriers are trapped by imperfections in the substrates or recombine and return to a non-charged neutral state. The network of conductive carriers can collect current over substantially the entire surface of the photovoltaic device. Carriers can be collected by relatively thin lines at relatively close spacing throughout the surface of the photovoltaic device and the combined current from these thin lines can flow through a few sparsely spaced and wider width bus lines to the edge of the photovoltaic device.

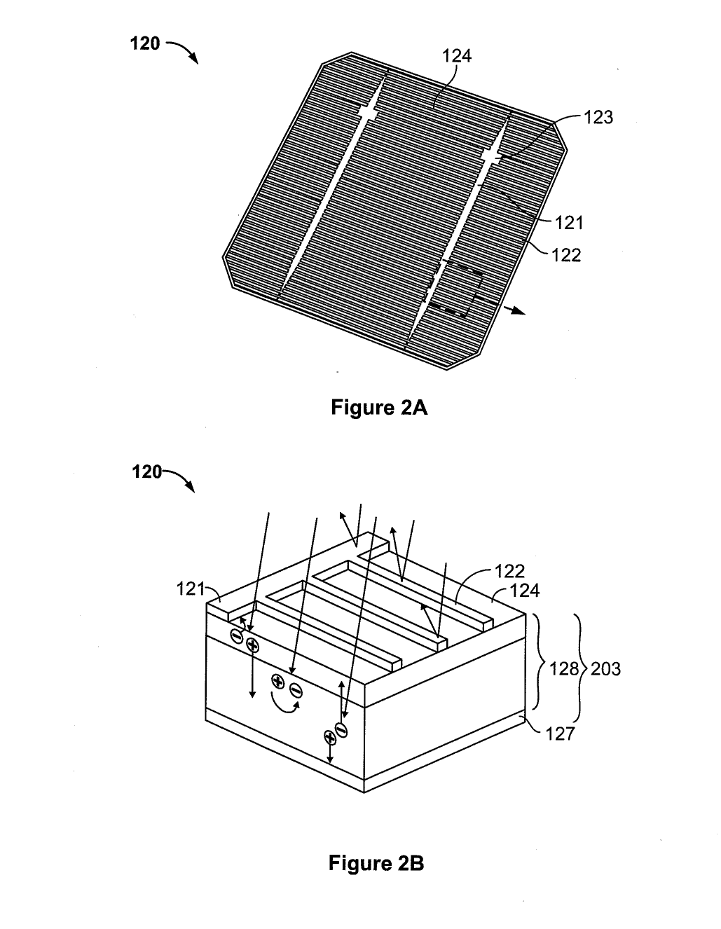

FIGS. 2A and 2B are examples of schematic plan and isometric sectional views depicting an example solar photovoltaic device with reflective electrodes on the front side. As illustrated in FIG. 2A, conductors on a light-incident or front side 124 of a device 120 can include larger bus electrodes 121 and/or smaller gridline electrodes 122. The bus electrodes 121 can also include larger pads 123 for soldering or electrically connecting a ribbon or tab (not shown). The electrodes 121, 122 can be patterned to reduce the distance an electron or hole travels to reach an electrode while also allowing enough light to pass through to the photovoltaic active layer(s). As illustrated in FIG. 2B, the photovoltaic device 120 can also include back electrodes 127, as well as a photovoltaic active region or photovoltaic active material 128 disposed between the front electrodes 121, 122 and the back electrodes 127.

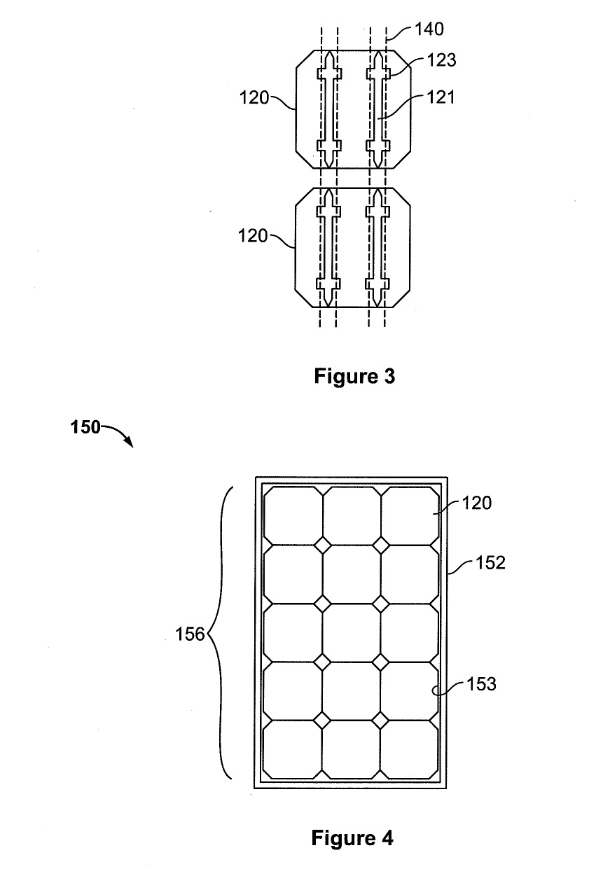

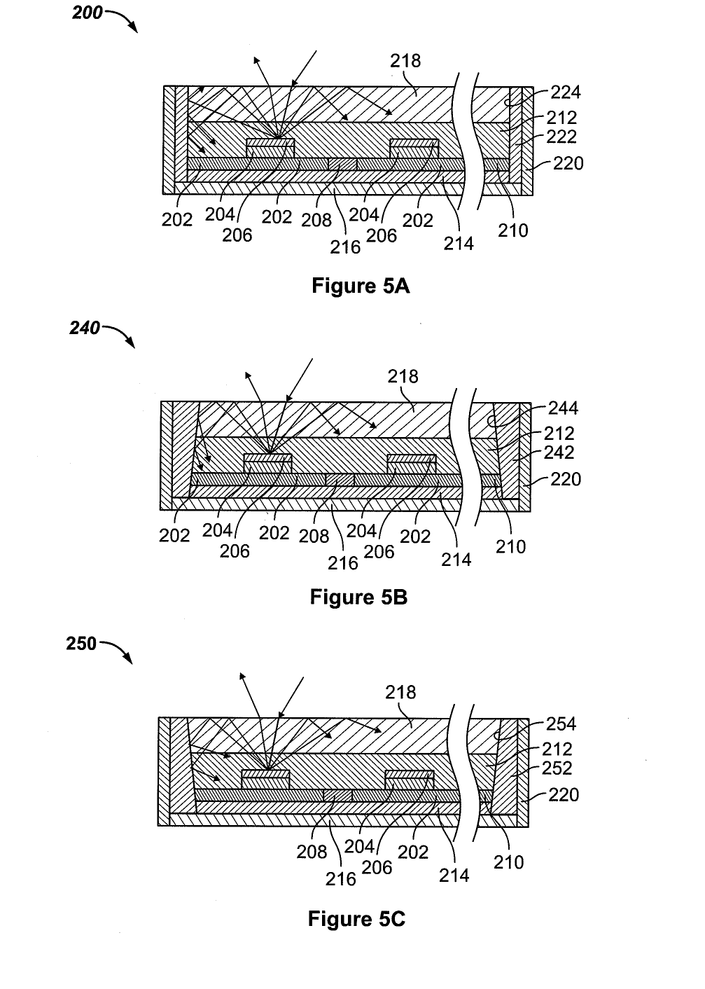

FIG. 3 schematically depicts an example of two photovoltaic cells connected by a tab or ribbon. In FIG. 3, two photovoltaic devices 120 are connected by a tab or ribbon 140. The ribbon 140 connects bus electrodes 121 or other electrodes across multiple photovoltaic devices 120, cells, dies, or wafers to form photovoltaic modules (as shown in FIG. 4), which can increase the output voltage by adding the voltage contributions of multiple photovoltaic devices 120 as may be desired according to the application. The ribbon 140 may be made of copper or other highly conductive material. This ribbon 140, like the bus 121 or gridline 122 electrodes, may reflect light, and may therefore also reduce the efficiency of the photovoltaic device 120.

FIG. 4 is an example of a schematic plan view of an array of a photovoltaic module 150 that includes a plurality of photovoltaic cells 120 arranged in an array 156. The photovoltaic cells 120 may be similar to the photovoltaic devices 120 depicted in FIGS. 2A and 2B. In some implementations, the array 156 of photovoltaic cells 120 can be electrically connected together with ribbons (not shown). The PV module 150 can include a frame 152 that is disposed along at least a portion of the edges of the array for supporting the array. The frame 152 can be configured to protect the edges of the array as well as any electrical components (e.g., bus lines) that may be disposed along the edges of the array. In some implementations, the frame structure supports the array and provides a strong structural member that can be connected to other supporting structure to position the PV module at a desired angle with respect to the sun. The composition of the frame 152 can include one or more metal materials (e.g., aluminum) or rigid non-metal materials. In some implementations, the frame can be configured to provide conductive bussing to route the electricity produced by the PV module to another conductive element and to downstream electrical devices or systems.

As illustrated in FIG. 4, some implementations can include a boundary reflector 154 (also referred to herein as a “reflector”) disposed at the periphery of the array 156, between the frame 152 and the edges of the array 156. For example, the boundary reflector 154 can be disposed along a portion of, or all of, the outside edge of the PV cells 120 that are arranged on the outer edges of the array 156. All or a portion of the outside edges of the PV cells 120 that are arranged on the outer edge of the array 156 is referred to herein as being an edge 153 of the array 156. The boundary reflector 154 can be positioned along the edge 153, and can be in contact with the edge 153. In some implementations, the boundary reflector 154 can be positioned adjacent to but not in contact with the edge 153 such that there is gap between the boundary reflector 154 and the edge 153. In some implementations, this gap can be filled with air or another material that does not absorb, or minimally absorbs, light.

The boundary reflector 154 includes a reflective surface that is configured to reflect light, that exits an edge 153 of the array 156, back through the edge 153 and into the array 156. For example, at least a portion of the light that has been caused to propagate in the array 154 and reflect from one or more internal surfaces of the PV cells in the array at relatively small angles (e.g., at angles resulting in total internal reflection), towards an edge of the array, and pass through an edge 153 of the array 156 falls incident on a reflective surface of a boundary reflector 154. The reflective surface is configured with a shape (e.g., convex) that advantageously redirects light that has exited the array through an edge of a PV cell back through the edge and into the array, thereby increasing the amount of light that can be incident on PV material disposed in the array 154. Re-introducing light, that has exited the array 156 along one or more portions of an edge 153, back into the array, increases the amount of light that eventually propagates to photovoltaic material disposed in the PV cells 120 of the array 156. In some implementations, the boundary reflector 154 can include a structure with a reflective surface. In some implementations, the boundary reflector 154 include at least one thin coating on another structure, such as, for example, a coating on an edge of the array or on a surface of the frame.

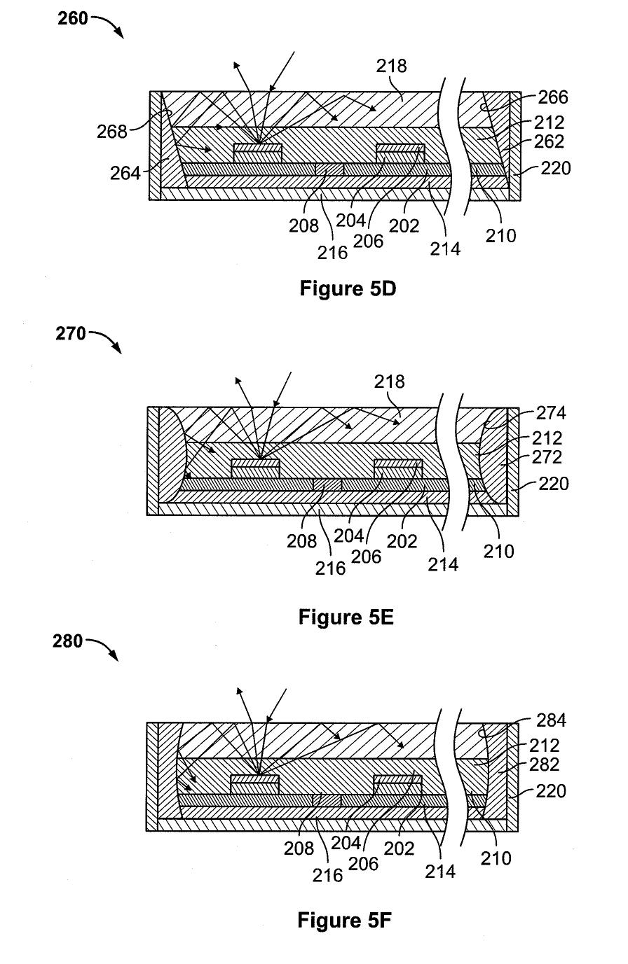

FIGS. 5A-5F show examples of cross-sectional views of various implementations of photovoltaic modules that include boundary reflectors positioned along at least a portion of an edge of an array of a PV module. As shown in FIGS. 5A-5F, in some implementations, the boundary reflectors can be configured to increase the amount of light that is totally internally reflected at an air/glass interface (e.g., at an interface between the air and a substrate layer) of the PV module. FIG. 5A shows a photovoltaic module 200 that includes multiple photovoltaic devices or cells 202. The cells 202 include photovoltaic active layers 210, conductors 204 formed on the active layers 210, and diffusers 206 formed on (or forward of) the conductors. As used herein, when used in the context of indicating a relative direction “forward” or “forward of” refers to a relative direction towards the portion (e.g., front surface) of the PV module, array or PV cell that is configured to receive incident light. The module 200 can include additional optical elements configured to redirect light (e.g., reflect, refract, or diffract light) that has entered PV cell but has not been absorbed by the PV active layers 210. In some implementations, the optical elements can be diffusers 208 disposed between adjacent cells 202 and/or diffusers 206 disposed on the conductors 204. The module 200 can include a transparent substrate layer 218 disposed forward of the cells 202. The substrate layer 218 can include, for example, glass or plastic. The module 200 can also include encapsulation layers 212, 214 which surround, or encapsulate, part or all of the cells 202. The encapsulation layers 212, 214 can include any suitable material, for example, ethylene vinyl acetate (also known as EVA or acetate). The encapsulation layer 212 can be configured with an index of refraction close to or matching the index of refraction of the substrate layer 218, such that light that has entered the PV module 200 and is propagating in the PV module 200 (e.g., in the substrate layer 218 or the encapsulation layer 212) is not significantly refracted at the interface between the substrate layer 218 and the encapsulation layer 212. The photovoltaic module 200 can further include a backing layer 216, which may include, for example, a polyvinyl fluoride film (Tedlar®) backsheet. In some implementations, a backsheet formed from glass or another polymer can be used. In some implementations, more or fewer layers may be used to form and package the module 200.

In the implementation illustrated in FIG. 5A, the PV module 200 includes a frame 220 which is disposed in the same plane as the array of PV cells and along the edge 153 of the PV cells, thereby surrounding the layers 210, 212, 214, 216, and 218. In the implementation illustrated in FIG. 5A, the PV module 200 also includes boundary reflectors 222 surrounding the layers 210, 212, 214, and 218. The reflectors 222 can be disposed at the edges 153 of the PV module 200, laterally between the outside edge 153 of PV cells 202 disposed on the outside portion of the PV module (or portions thereof) and the frame 220. The reflectors 222 include reflective surfaces 224 that are configured to reflect at least a portion of light that is exiting the PV cells along an edge of the PV cell back into the PV cells. Without the reflective surfaces 224, the light propagating toward the frame at the edges of the module 200 might otherwise be absorbed by the frame 220 or other material (e.g., glue) surrounding the cells 202, or be reflected in a direction such that it does not re-enter a PV cell.

In some implementations, the reflective surfaces 224 can extend in a direction from a back side 201 of the array to a forward side 203 upon which light is incident. The arrows in FIG. 5A illustrate examples of how incident light may be reflected off the diffuser 208, the forward internal surface of the transparent substrate 218, and the reflective surfaces 224. In some implementations, as illustrated in FIG. 5A, the reflective surfaces 224 can extend in a direction normal to the plane of the photovoltaic active material 210. As illustrated in FIG. 5A, the reflective surfaces 224 can be planar. In some implementations, a reflective surface can include both curved and planar portions. In some implementations, the reflective surfaces can be curved and/or contoured, or have multiple planar and/or curved portions. In some implementations, the reflectors 222 can include, for example, a metal with a polished surface, such as polished aluminum, chromium, titanium, or tungsten. The reflectors need not be a structure separate from the frame 220, but may instead include a reflective coating formed on a surface of the frame 220.

FIG. 5B shows another photovoltaic module 240 including photovoltaic cells 202 with photovoltaic active layers 210, encapsulation layers 212, 214, a front substrate 218 and a backing layer 216. The module 240 includes boundary reflectors 242 having planar reflective surfaces 244 which are disposed at an angle to the plane of the photovoltaic active layer 210. In the implementation of FIG. 5B, the reflective surfaces 244 are disposed at an acute angle with respect to the cells 202. FIG. 5C shows a photovoltaic module 250 having reflectors 252 with reflective surfaces 254 disposed at an obtuse angle with respect to the cells 202. FIG. 5D shows a photovoltaic module 260 having reflectors 262, 264 with reflective surfaces 266, 268 disposed at different angles with respect to the cells 202. In the module 260, the reflective surface 266 is disposed at an obtuse angle with respect to the cells 202, while the reflective surface 268 at the opposite side of the module is disposed at an acute angle with respect to the cells 202. In implementations, a reflective surface can be disposed at any suitable angle with respect to the array, including, for example, 70°, 75°, 80°, 85°, 90°, 95°, 100°, 105°, 110°, an angle greater than or less than any of these listed angles, or an angle in a range defined by any of these listed angles.

As illustrated in FIG. 5E, a photovoltaic module 270 can include boundary reflectors 272 having convex reflective surfaces 274. In some implementations, convex reflective surfaces can be employed to redirect light toward the photovoltaic active material, toward a diffuser forming part of the module, and/or toward the forward internal surface of the transparent substrate.

In another implementation, as illustrated in FIG. 5F, a photovoltaic module 280 can include boundary reflectors 282 having concave reflective surfaces 284. In some implementations, a concave reflective surface can be oriented at an angle so as to focus reflected light toward a particular region of a photovoltaic module, such as, for example, the photovoltaic active layer or a diffuser forming part of the photovoltaic module.

In some implementations, as illustrated in FIGS. 5A-5C, boundary reflectors can be provided directly adjacent to the edges of the photovoltaic active layer 210. As also illustrated in FIGS. 5A-5C, the boundary reflectors can be provided directly adjacent the edges of the transparent substrate layer 218 and the edges of the encapsulation layers 212, 214.

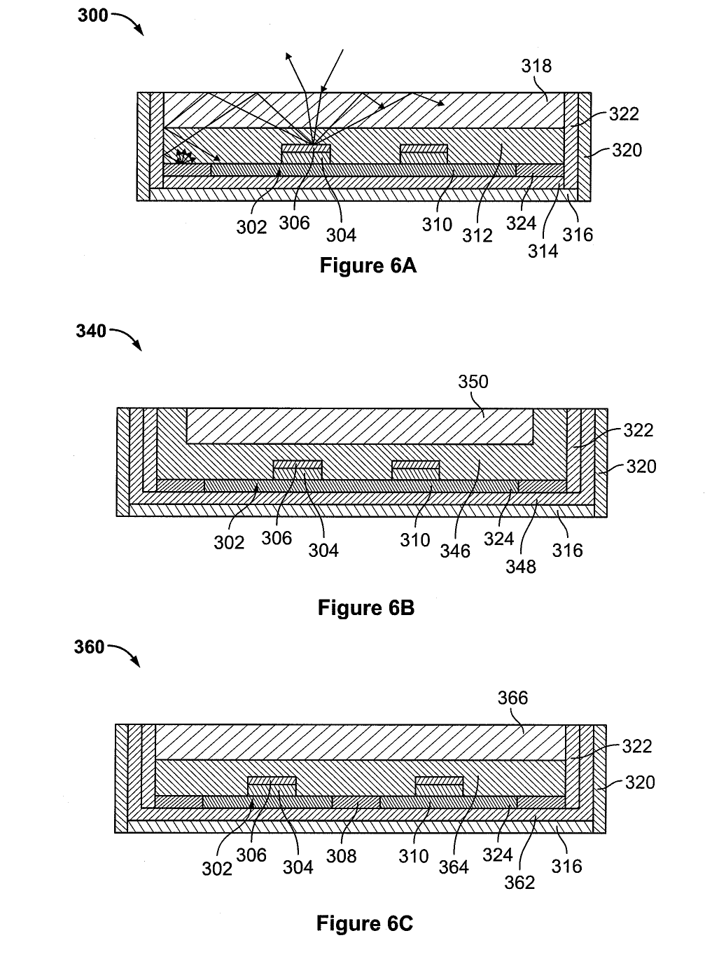

FIGS. 6A-6C show examples of cross-sectional views of additional implementations of photovoltaic modules including boundary reflectors. FIG. 6A shows a photovoltaic module 300 that includes one or more photovoltaic devices or cells 302. The cells 302 include photovoltaic active layers 310, conductors 304 formed on the active layers 310, and diffusers 306 formed on (or forward of) the conductors. The module 300 includes a transparent substrate layer 318 disposed forward of the cells 302, as well as encapsulation layers 312, 314 encapsulating the cells 302 and a backing layer 316 disposed behind the encapsulated cells 302. In the implementation illustrated in FIG. 6A, the photovoltaic active layers 310 are surrounded at the edges of the module 300 by diffusers 324. The diffusers 324 can be encapsulated within the encapsulation layers 312, 314. The layers 310, 312, 314, 316, and 318 are surrounded by a frame 320, with boundary reflectors 322 disposed between the layers 310, 312, 314, and 318 and the frame 320. The diffusers 324 cooperate with the boundary reflectors 322 to direct light traveling near the edges of the module 300 back toward the photovoltaic active layer 310 (or toward other reflective surfaces in the module 300). Although the reflectors 322 are illustrated in FIG. 6A as extending across the entire thickness of the layers 310, 312, 314, and 318, in some implementations, the reflectors can be longer or shorter. For example, in some implementations, the reflectors can extend vertically across the thickness of the layers 310, 312, 314 and stopping short of the transparent layer 318 or extending partway across the thickness of transparent layer 318.

FIG. 6B shows another example of a photovoltaic module 340 that includes one or more photovoltaic devices or cells 302. In the implementation illustrated in FIG. 6B, the boundary reflectors 322 are disposed at the edges of the module 340, between the cells 302 and the frame 320. The boundary reflectors 322 are also encapsulated between encapsulation layers 346, 348 along with the photovoltaic active layer 310, conductors 304, and edge diffusers 324. A transparent substrate 350 overlies the cells 302. At the edges of the module 340, the encapsulation layer 348 is disposed laterally between the reflectors 322 and the frame and the encapsulation layer 346 is disposed laterally between the transparent substrate 350 and each reflector 322.

FIG. 6C shows another example of a photovoltaic module 360 that includes one or more photovoltaic cells 302. At the edges of the module 360, a lower encapsulation layer 362 is disposed laterally between the boundary reflectors 322 and the frame 320, while an upper encapsulation layer 364 is disposed laterally between the transparent substrate 366 and each reflector 322. The module 360 can also include additional optical elements configured to reflect and/or diffuse incident light, such as, for example, diffuser 208 which can be formed between adjacent cells 202.

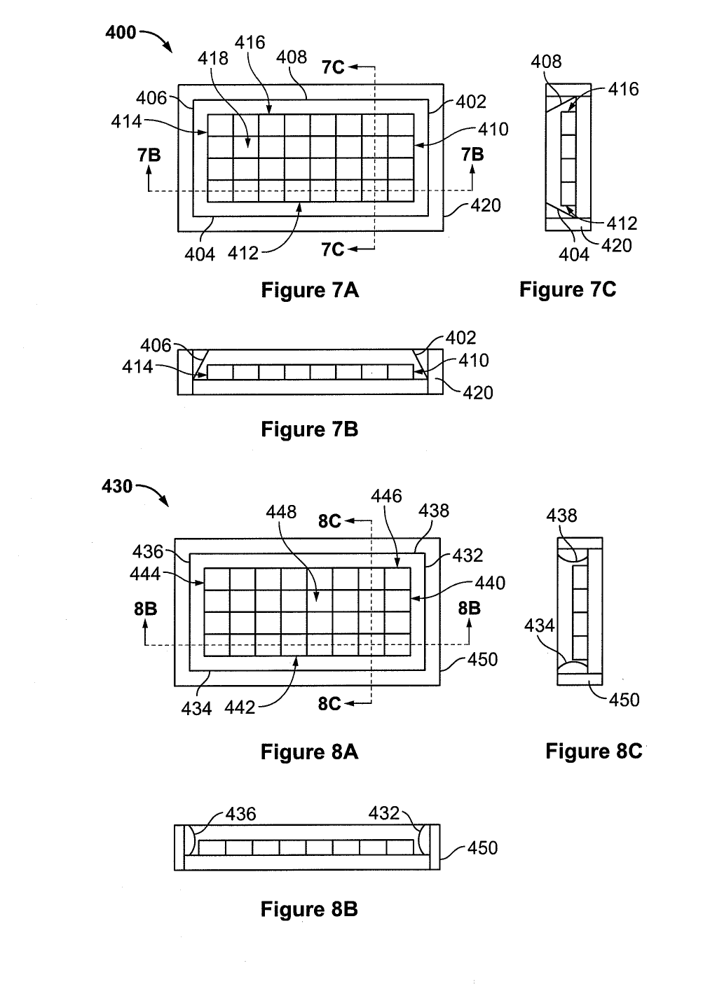

In some implementations, the boundary reflectors and/or the reflective surfaces can have the same configuration on all edges of a photovoltaic module. FIGS. 7A, 7B, and 7C are examples of schematic plan and cross-sectional views of a photovoltaic module according to one implementation.

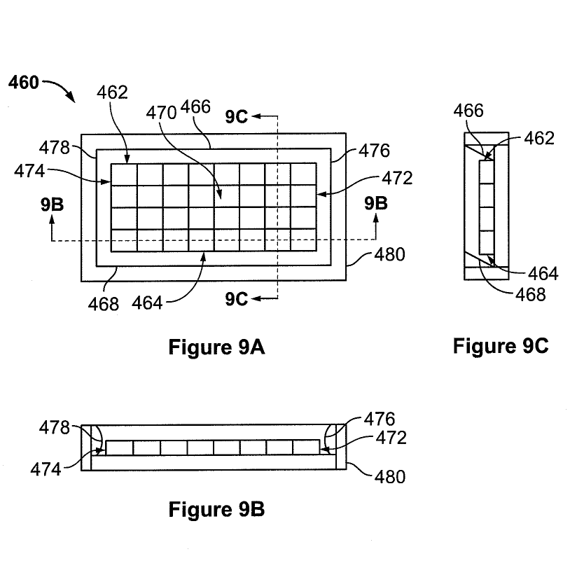

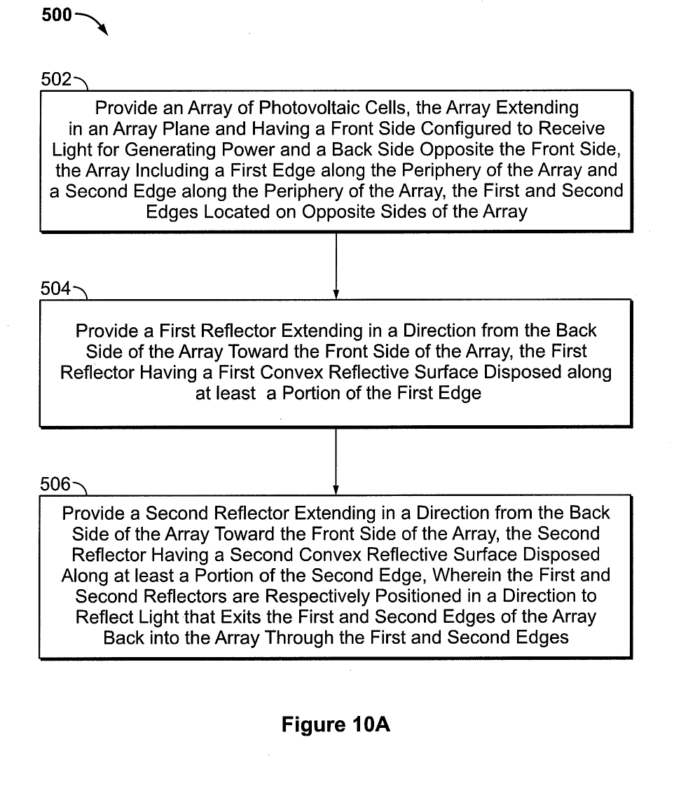

As illustrated in FIGS. 7A-7C, a rectangular photovoltaic module 400 can have planar reflective surfaces 402, 404, 406, and 408 on all four edges 410, 412, 414, and 416, with each surface 402, 404, 406, and 408 disposed at an acute angle with respect to an array 418, between the array 418 and a surrounding frame 420. FIGS. 8A, 8B, and 8C are examples of schematic plan and cross-sectional views of a photovoltaic module according to another implementation. As shown in FIGS. 8A-8C, a rectangular photovoltaic module 430 can have convex reflective surfaces 432, 434, 436, and 438 on all four edges 440, 442, 444, and 446 of an array 448, between the array 448 and a surrounding frame 450. In other implementations, a photovoltaic module can include boundary reflectors and/or reflective surfaces that are configured differently on different edges of the module. FIGS. 9A, 9B, and 9C are examples of schematic plan and cross-sectional views of a photovoltaic module according to yet another implementation. As shown in FIGS. 9A-9C, in some implementations, a rectangular photovoltaic module 460 can have first and second opposing edges 462, 464 having planar reflective surfaces 466, 468 extending at obtuse and acute angles, respectively, with respect to the plane of an array 470, while third and fourth opposing edges 472, 474 include curved reflective surfaces 476, 478 between the array 470 and a surrounding frame 480.

In some implementations, the shape and/or orientation of boundary reflectors or reflective surfaces with respect to the plane of the array can be selected to optimize the efficiency of a module for a selected geographical location, e.g., a particular latitude, and/or a selected time, e.g., a selected time of day or a particular season. For example, during the summer at 40° latitude, a module might be tilted to point approximately 16.5° from directly overhead in order to point it directly at the sun. To improve the efficiency of the module for this particular application, the module can be designed with convex reflectors on the side edges of the array, an acutely-angled reflector on the bottom edge (e.g., a reflector disposed at roughly 30° with respect to the plane of the array), and an obtusely-angled reflector on the top edge of the array (e.g., a reflector disposed at roughly 120° with respect to the plane of the array) in the array's tilted position. By such a configuration, the reflectors may act to increase the amount of light that is directed to the photovoltaic active layer of the array and thereby increase the overall power output of the module.

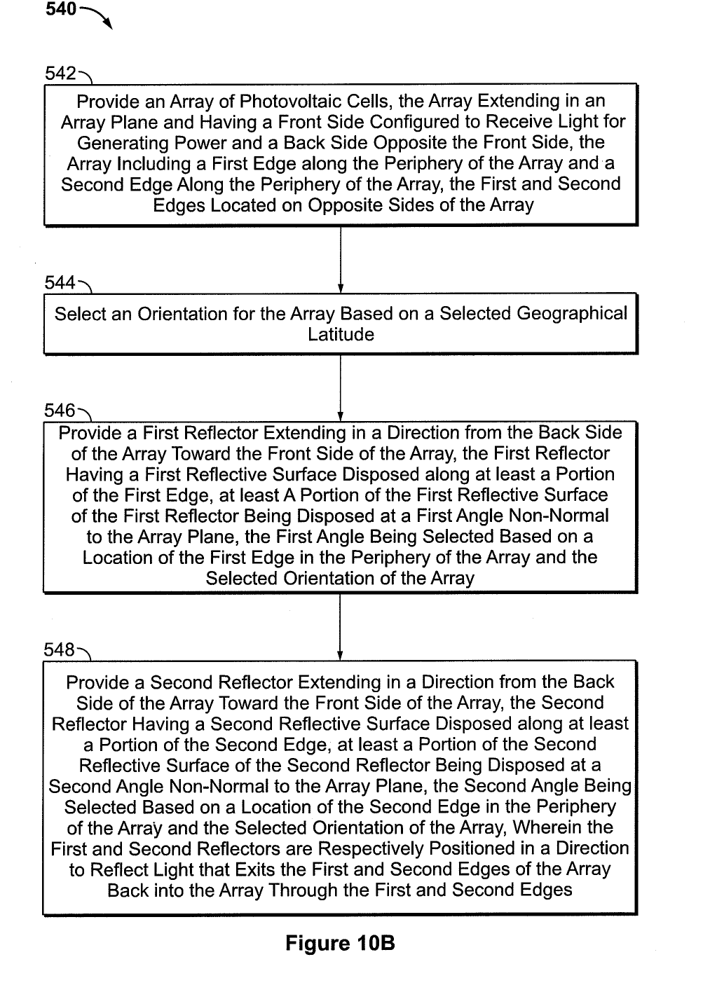

FIG. 10A is an example of a block diagram schematically illustrating one implementation of a method of manufacturing a photovoltaic module. As illustrated in block 502, method 500 includes providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array. In some implementations, the photovoltaic cells can be similar to the photovoltaic cells 100, 110, 120, 203, and/or 302 illustrated in FIGS. 1A, 1B, 2A, 2B, 3, 4, 5A-5F, and 6A-6C.

As shown in block 504, the method 500 can also include providing a first reflector extending in a direction from the back side of the array toward the front side of the array, the first reflector having a first convex reflective surface disposed along at least a portion of the first edge.

As shown in block 506, the method 500 can also include providing a second reflector extending in a direction from the back side of the array toward the front side of the array, the second reflector having a second convex reflective surface disposed along at least a portion of the second edge, wherein the first and second reflectors are respectively positioned in a direction to reflect light that exits the first and second edges of the array back into the array through the first and second edges. In some implementations, the reflective surfaces can be similar to the reflective surfaces 274 illustrated in FIG. 5E or the reflective surfaces 432, 436 illustrated in FIGS. 8A-8C. In some implementations, the reflective surfaces can be provided during a process for forming the array. For example, in some implementations, the reflective surfaces can be placed around one or more edges of the array prior to a lamination process in which the photovoltaic cells of the array are encapsulated in an encapsulation material. In such an implementation, the reflective surfaces can be encapsulated with the photovoltaic cells. In other implementations, the reflective surfaces can be placed around one or more edges of the array after the cells are encapsulated. In still other implementations, the reflective surfaces can be provided on an inner surface of a frame before the frame is provided around the array. For example, the reflective surfaces can be provided by polishing an inner surface of the frame, by coating the inner surface of the frame with a reflective material, or by attaching a structure with a reflective surface to an inner surface of the frame.

FIG. 10B is an example of a block diagram schematically illustrating another implementation of a method of manufacturing a photovoltaic module. As illustrated in block 542, method 540 includes providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array. In some implementations, the photovoltaic cells can be similar to the photovoltaic cells 100, 110, 120, 203, and/or 302 illustrated in FIGS. 1A, 1B, 2A, 2B, 3, 4, 5A-5F, and 6A-6C.

As shown in block 544, the method 540 can also include selecting an orientation for the array based on a selected geographical latitude. As shown in block 546, the method 540 can also include providing a first reflector extending in a direction from the back side of the array toward the front side of the array, the first reflector having a first reflective surface disposed along at least a portion of the first edge, at least a portion of the first reflective surface of the first reflector being disposed at a first angle non-normal to the array plane, the first angle being selected based on a location of the first edge in the periphery of the array and the selected orientation of the array. As shown in block 548, the method 540 can also include providing a second reflector extending in a direction from the back side of the array toward the front side of the array, the second reflector having a second reflective surface disposed along at least a portion of the second edge, at least a portion of the second reflective surface of the second reflector being disposed at a second angle non-normal to the array plane, the second angle being selected based on a location of the second edge in the periphery of the array and the selected orientation of the array, wherein the first and second reflectors are respectively positioned in a direction to reflect light that exits the first and second edges of the array back into the array through the first and second edges. In some implementations, the reflective surfaces can be similar to the reflective surfaces 224, 244, 254, 264, 274, 284, 322, 402, 404, 406, 408, 432, 434, 436, and/or 438 illustrated in FIGS. 5A-5F, 6A-6C, 7A-5C, 8A-8C, and 9A-9C. In some implementations, the orientation of the array, the angle(s) the reflective surfaces, and/or the curvature (if any) of the reflective surfaces can be selected based on the average angle of the sun (e.g., over a day, a season, or a year) for a particular geographical location.

In some implementations, the first and second reflective surfaces can be provided during a process for forming the array. For example, in some implementations, the reflective surfaces can be placed around one or more edges of the array prior to a lamination process in which the photovoltaic cells of the array are encapsulated in an encapsulation material. In such an implementation, the reflective surfaces can be encapsulated with the photovoltaic cells. In other implementations, the reflective surfaces can be placed around one or more edges of the array after the cells are encapsulated. In still other implementations, the reflective surfaces can be provided on an inner surface of a frame before the frame is provided around the array. For example, the reflective surfaces can be provided by polishing an inner surface of the frame, by coating the inner surface of the frame with a reflective material, or by attaching a structure with a reflective surface to an inner surface of the frame.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with the disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the photovoltaic cell as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array;
a first reflector extending in a direction from the back side of the array toward the front side of the array, the first reflector having a first convex reflective surface disposed along at least a portion of the first edge; and
a second reflector extending in a direction from the back side of the array toward the front side of the array, the second reflector having a second convex reflective surface disposed along at least a portion of the second edge,
wherein the first and second reflectors are respectively positioned in a direction to reflect light that exits the first and second edges of the array back into the array through the first and second edges.

2. The apparatus of claim 1, further comprising a frame disposed along at least the first and second edges of the array, wherein the first and second reflectors are respectively located between the frame and the first and second edges of the array.

3. The apparatus of claim 1, wherein each photovoltaic cell includes a photovoltaic active layer, and wherein at least one of the first and second reflective surfaces is spaced apart laterally from the photovoltaic active layer of at least one of the photovoltaic cells.

4. The apparatus of claim 3, further comprising an optical element disposed between the photovoltaic active layer and the at least one of the first and second reflective surfaces.

5. The apparatus of claim 1, wherein the array further includes a third edge along the periphery of the array and a fourth edge along the periphery of the array, the third and fourth edges located on opposite sides of the array, the third and fourth edges extending in a direction normal to the first and second edges, and wherein the apparatus further comprises:
a third reflector extending in a direction from the back side of the array toward the front side of the array, the third reflector having a third reflective surface disposed along at least a portion of the third edge, at least a portion of the third reflective surface being disposed at a third angle with respect to the array plane; and
a fourth reflector extending in a direction from the back side of the array toward the front side of the array, the fourth reflector having a fourth reflective surface disposed along at least a portion of the fourth edge, at least a portion of the fourth reflective surface being disposed at a fourth angle with respect to the array plane,
wherein the third and fourth reflectors are respectively positioned in a direction to reflect light that exits the third and fourth edges of the array back into the array through the third and fourth edges, and
wherein and the third and fourth angles are selected based on a selected geographical latitude and a corresponding selected orientation of the array relative to the sun.

6. The apparatus of claim 5, wherein at least one of the third and fourth angles is an acute angle with respect to the array plane.

7. The apparatus of claim 5, wherein both the third and fourth angles are acute angles with respect to the array plane.

8. A method comprising:
providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array;
providing a first reflector extending in a direction from the back side of the array toward the front side of the array, the first reflector having a first convex reflective surface disposed along at least a portion of the first edge; and
providing a second reflector extending in a direction from the back side of the array toward the front side of the array, the second reflector having a second convex reflective surface disposed along at least a portion of the second edge,
wherein the first and second reflectors are respectively positioned in a direction to reflect light that exits the first and second edges of the array back into the array through the first and second edges.

9. The method of claim 8, further comprising providing a frame disposed along at least the first and second edges of the array, wherein the first and second reflectors are respectively located between the frame and the first and second edges of the array.

10. A method of manufacturing a photovoltaic module, the method comprising:
providing an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array;
selecting an orientation for the array based on a selected geographical latitude;
providing a first reflector extending in a direction from the back side of the array toward the front side of the array, the first reflector having a first reflective surface disposed along at least a portion of the first edge, at least a portion of the first reflective surface of the first reflector being disposed at a first angle non-normal to the array plane, the first angle being selected based on a location of the first edge in the periphery of the array and the selected orientation of the array; and
providing a second reflector extending in a direction from the back side of the array toward the front side of the array, the second reflector having a second reflective surface disposed along at least a portion of the second edge, at least a portion of the second reflective surface of the second reflector being disposed at a second angle non-normal to the array plane, the second angle being selected based on a location of the second edge in the periphery of the array and the selected orientation of the array,
wherein the first and second reflectors are respectively positioned in a direction to reflect light that exits the first and second edges of the array back into the array through the first and second edges.

11. The method of claim 10, further comprising providing a frame disposed along at least the first and second edges of the array, wherein the first and second reflectors are respectively located between the frame and the first and second edges of the array.

12. The method of claim 10, wherein the first angle is an acute angle with respect to the array plane and the second angle is an obtuse angle with respect to the array plane.

13. The method of claim 10, wherein each photovoltaic cell includes a photovoltaic active layer, and wherein at least one of the first and second reflective surfaces is spaced apart laterally from the photovoltaic active layer of at least one of the photovoltaic cells.

14. The method of claim 10, further comprising providing an optical element disposed between the photovoltaic active layer and the at least one of the first and second reflective surfaces.

15. An apparatus comprising:
an array of photovoltaic cells, the array extending in an array plane and having a front side configured to receive light for generating power and a back side opposite the front side, the array including a first edge along the periphery of the array and a second edge along the periphery of the array, the first and second edges located on opposite sides of the array;
a first reflector extending in a direction from the back side of the array toward the front side of the array, the first reflector having a first reflective surface disposed along at least a portion of the first edge, at least a portion of the first reflective surface of the first reflector being disposed at a first angle non-normal to the array plane; and
a second reflector extending in a direction from the back side of the array toward the front side of the array, the second reflector having a second reflective surface disposed along at least a portion of the second edge, at least a portion of the second reflective surface of the second reflector being disposed at a second angle non-normal to the array plane, and
wherein the first and second reflectors are respectively positioned in a direction to reflect light that exits the first and second edges of the array back into the array through the first and second edges.

16. The apparatus of claim 15, wherein the first and second angles are selected based on a selected geographical latitude and a corresponding selected orientation of the array relative to the sun

17. The apparatus of claim 15, wherein the first angle is an acute angle with respect to the array plane and the second angle is an obtuse angle with respect to the array plane.

18. The apparatus of claim 17, wherein the first angle is between about 20° and 40° and the second angle is between about 110° and 130°.

19. The apparatus of claim 17, wherein the first angle is approximately 30° with respect to the array plane and the second angle is approximately 120° with respect to the array plane.

20. The apparatus of claim 17, wherein each photovoltaic cell includes a photovoltaic active layer, and wherein at least one of the first and second reflective surfaces is spaced apart laterally from the photovoltaic active layer of at least one of the photovoltaic cells.

21. The apparatus of claim 20, further comprising an optical element disposed between the photovoltaic active layer and the at least one of the first and second reflective surfaces.
